(19) United States
(12) Patent Application Publication
(10) Pub. No.: US 2024/0162017 A1
(43) Pub. Date: May 16, 2024

(54) SUBSTRATE SUPPORTING DEVICE, A SUBSTRATE PROCESSING APPARATUS INCLUDING THE SAME, AND A SUBSTRATE PROCESSING METHOD USING THE SAME

(71) Applicant: Samsung Electronics Co., Ltd., Suwon-si (KR)

(72) Inventors: Heewon MIN, Suwon-si (KR); Juho KIM, Suwon-si (KR); Dongyun YEO, Suwon-si (KR); Kuihyun YOON, Suwon-si (KR); Seungbin LIM, Suwon-si (KR); Songyun KANG, Suwon-si (KR); Youngrok KWON, Suwon-si (KR)

(73) Assignee: Samsung Electronics Co., Ltd., Suwon-si (KR)

(21) Appl. No.: 18/327,458

(22) Filed: Jun. 1, 2023

(30) Foreign Application Priority Data
Nov. 11, 2022 (KR) 10-2022-0150591

(51) Int. Cl. H01J 37/32

(52) U.S. Cl. CPC H01J 37/32724; H01J 2237/002; H01J 2237/2007; H01J 2237/334

(57) ABSTRACT

A substrate supporting device may include a cooling plate including a cooling hole, a thermal-insulation plate on the cooling plate, and a chucking plate placed on the thermal-insulation plate. The chucking plate may include a heater. The thermal-insulation plate may include an adiabatic space, which is recessed from a top surface of the thermal-insulation plate by a depth in a downward direction. The cooling plate may include a connection hole, which vertically extends and is connected to the adiabatic space.

### CROSS-REFERENCE TO RELATED APPLICATIONS

This U.S. non-provisional patent application claims priority under 35 U.S.C. § 119 to Korean Patent Application No. 10-2022-0150591, filed on Nov. 11, 2022, in the Korean Intellectual Property Office, the entire contents of which are hereby incorporated by reference.

### BACKGROUND

The present disclosure relates to substrate supporting devices configured to heat a substrate to a high temperature, substrate processing apparatuses including the same, and/or substrate processing methods using the same.

A semiconductor device is fabricated through various processes. For example, the fabrication of the semiconductor device includes a deposition process, a photolithography process, an etching process, a test process, and a cleaning process, which are performed on a substrate. In each of the fabrication processes, a stage is used to support the substrate. The stage is configured to fasten the substrate and to adjust a temperature of the substrate. For example, the stage is configured to heat the substrate.

### SUMMARY

Some example embodiments of the inventive concepts provide substrate supporting devices, which are configured to heat a substrate to a high temperature, substrate processing apparatuses including the same, and/or substrate processing methods using the same.

Some example embodiments of the inventive concepts provide substrate supporting devices, which are configured to prevent its components from being thermally damaged, substrate processing apparatuses including the same, and/or substrate processing methods using the same.

Some example embodiments of the inventive concepts provide substrate supporting devices, which are configured to quickly control a temperature of a substrate when desired, substrate processing apparatuses including the same, and/or substrate processing methods using the same.

Some example embodiments of the inventive concepts provide substrate supporting devices, which are configured to suppress a deformation issue caused by thermal expansion, substrate processing apparatuses including the same, and/or substrate processing methods using the same.

Some example embodiments of the inventive concepts provide substrate supporting devices, which are configured to independently control temperatures of edge and center regions of a substrate, substrate processing apparatuses including the same, and/or substrate processing methods using the same.

According to an example embodiment of the inventive concepts, a substrate supporting device may include a cooling plate including a cooling hole, a thermal-insulation plate on the cooling plate, and a chucking plate placed on the thermal-insulation plate. The chucking plate may include a heater. The thermal-insulation plate may include an adiabatic space, which is recessed from a top surface of the thermal-insulation plate by a depth in a downward direction. The cooling plate may include a connection hole, which extends vertically and is connected to the adiabatic space.

According to an example embodiment of the inventive concepts, a substrate supporting device may include a cooling plate with a cooling hole, a chucking plate on the cooling plate, and a supporting structure configured to support a bottom surface of the chucking plate. The chucking plate may be vertically separated from the cooling plate by an adiabatic space, which is sealed and under the chucking plate to expose the bottom surface of the chucking plate and the supporting structure may be placed in the adiabatic space. The cooling plate may include a connection hole connected to the adiabatic space. The supporting structure may include a supporting block and a cap, which is coupled to the supporting block and configured to be in contact with the bottom surface of the chucking plate.

According to an example embodiment of the inventive concepts, a substrate processing apparatus may include a process chamber including a process space, and a substrate supporting device in the process chamber. The substrate supporting device may include a cooling plate with a cooling hole, a chucking plate on the cooling plate, the chucking plate including a heater, and a plurality of supporting structures configured to support a bottom surface of the chucking plate. The chucking plate may be vertically separated from the cooling plate by an adiabatic space, which is sealed and under the chucking plate to expose the bottom surface of the chucking plate. The plurality of supporting structures may include a first supporting structure and a second supporting structure, the first supporting structure spaced apart from an axis of the chucking plate by a first distance, the second supporting structure spaced apart from the axis by a second distance. Here, a size of the first supporting structure may be larger than a size of the second supporting structure.

According to an example embodiment of the inventive concepts, a substrate processing method may include disposing a substrate on a substrate supporting device, applying a vacuum pressure to an adiabatic space, which is provided between a chucking plate and a cooling plate of the substrate supporting device, and applying a heating power to a heater of the chucking plate while applying the vacuum pressure to the adiabatic space.

### BRIEF DESCRIPTION OF THE DRAWINGS

FIG. 1 is a sectional view illustrating a substrate processing apparatus according to an example embodiment of the inventive concepts.

FIG. 2 is a sectional view illustrating a substrate supporting device according to an example embodiment of the inventive concepts.

FIG. 3 is an exploded sectional view illustrating a substrate supporting device according to an example embodiment of the inventive concepts.

FIG. 4 is an enlarged sectional view illustrating a portion ‘X’ of FIG. 2.

FIG. 5 is a sectional view illustrating a supporting structure of a substrate supporting device according to an example embodiment of the inventive concepts.

FIG. 6 is a perspective view illustrating a supporting structure of a substrate supporting device according to an example embodiment of the inventive concepts.

FIG. 7 is a plan view illustrating a thermal-insulation plate including a plurality of substrate supporting devices according to an example embodiment of the inventive concepts.

FIG. 8 is an enlarged plan view illustrating a portion ‘Y’ of FIG. 7.

FIG. 9 is a flow chart illustrating a substrate processing method according to an example embodiment of the inventive concepts.

FIGS. 10 to 15 are diagrams sequentially illustrating the substrate processing method according to the flow chart of FIG. 9.

FIG. 16 is a sectional view illustrating a substrate processing apparatus according to an example embodiment of the inventive concepts.

FIG. 17 is an enlarged sectional view illustrating a portion ‘Xa’ of FIG. 16.

FIG. 18 is a sectional view illustrating a supporting structure of a substrate supporting device according to an example embodiment of the inventive concepts.

### DETAILED DESCRIPTION

Example embodiments of the inventive concepts will now be described more fully with reference to the accompanying drawings, in which some example embodiments are shown.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

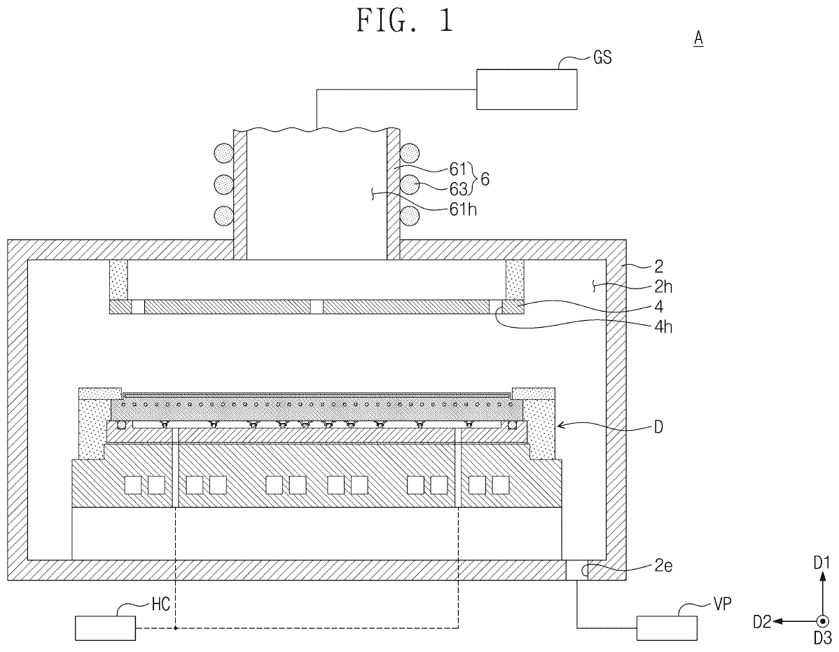

FIG. 1 is a sectional view illustrating a substrate processing apparatus according to an example embodiment of the inventive concepts.

In the present application, reference numbers D1, D2, and D3 will be used to denote a first direction, a second direction, and a third direction, respectively, which are not parallel to each other. The first direction D1 may be referred to as a vertical direction. In addition, each of the second and third directions D2 and D3 may be referred to as a horizontal direction.

Referring to FIG. 1, a substrate processing apparatus A may be provided. The substrate processing apparatus A may be configured to perform an etching process and/or a deposition process on a substrate. In the present specification, the term “substrate” may mean a silicon wafer, but the inventive concepts are not limited to this example. The substrate processing apparatus A may be configured to perform an etching process and/or a deposition process on the substrate using plasma. In the substrate processing apparatus A, various methods may be used to generate the plasma. For example, the substrate processing apparatus A may include an inductively-coupled plasma (ICP) device or a capacitively-coupled Plasma (CCP) device. For brevity's sake, the description that follow will be given based on the ICP device, but the inventive concepts are not limited to this example. The substrate processing apparatus A may include a process chamber 2, a substrate supporting device D, a gas distribution device 4, a plasma generating device 6, a gas supplying device GS, a vacuum pump VP, and a heat-transfer fluid control device HC.

The process chamber 2 may be configured to provide a process space 2h. A process on the substrate may be performed in the process space 2h. The process space 2h may be connected to each of the gas supplying device GS and the vacuum pump VP.

The substrate supporting device D may be disposed in the process chamber 2. The substrate supporting device D may be configured to support and/or fasten the substrate. For example, the substrate supporting device D may fasten the substrate to a desired (or alternatively, predetermined) position using an electrostatic force. That is, the substrate supporting device D may be an electrostatic chuck (ESC). However, the inventive concepts are not limited to this example, and in an example embodiment, the substrate supporting device D may include a different type of chuck. In addition, the substrate supporting device D may be configured to adjust a temperature of the substrate. For example, the substrate supporting device D may be configured to heat the substrate and to increase the temperature of the substrate. The substrate supporting device D will be described in more detail below.

The gas distribution device 4 may be disposed in the process chamber 2. The gas distribution device 4 may be spaced apart from the substrate supporting device D in an upward direction. The gas distribution device 4 may be provided to have a gas distribution hole 4h. A process gas may be supplied from the gas supplying device GS into the process space 2h through the gas distribution hole 4h.

The plasma generating device 6 may be combined or coupled to the process chamber 2. For example, the plasma generating device 6 may be placed on the process chamber 2. However, the inventive concepts are not limited to this example, and in an example embodiment, the plasma generating device 6 may be disposed in the process chamber 2. The plasma generating device 6 may include a gas supplying pipe 61 and a coil 63. The gas supplying pipe 61 may be configured to provide a gas supplying path 61h. The gas supplying path 61h may connect the gas supplying device GS to the process space 2h. The coil 63 may be provided to enclose the gas supplying pipe 61. If a power is applied to the coil 63, a gas in the gas supplying path 61h may be transformed to plasma.

The gas supplying device GS may be connected to the process space 2h. The gas distribution device 4 may supply the process gas into the process space 2h. For this, the gas distribution device 4 may include a gas tank, a compressor, and/or a gas valve.

The vacuum pump VP may be connected to the process space 2h. For example, the vacuum pump VP may be connected to the process space 2h through an exhausting hole 2e, which is formed in the process chamber 2. The vacuum pump VP may be used to exhaust a fluidic material in the process space 2h to the outside of the process space 2h.

The heat-transfer fluid control device HC may be connected to the substrate supporting device D. The heat-transfer fluid control device HC may supply a heat-transfer fluid into the substrate supporting device D. For this, the heat-transfer fluid control device HC may include a heat-transfer fluid tank, a compressor, and so forth. In addition, the heat-transfer fluid control device HC may be configured to exhaust the heat-transfer fluid from the substrate supporting device D. For this, the heat-transfer fluid control device HC may include a pump and so forth. The heat-transfer fluid control device HC will be described in more detail below.

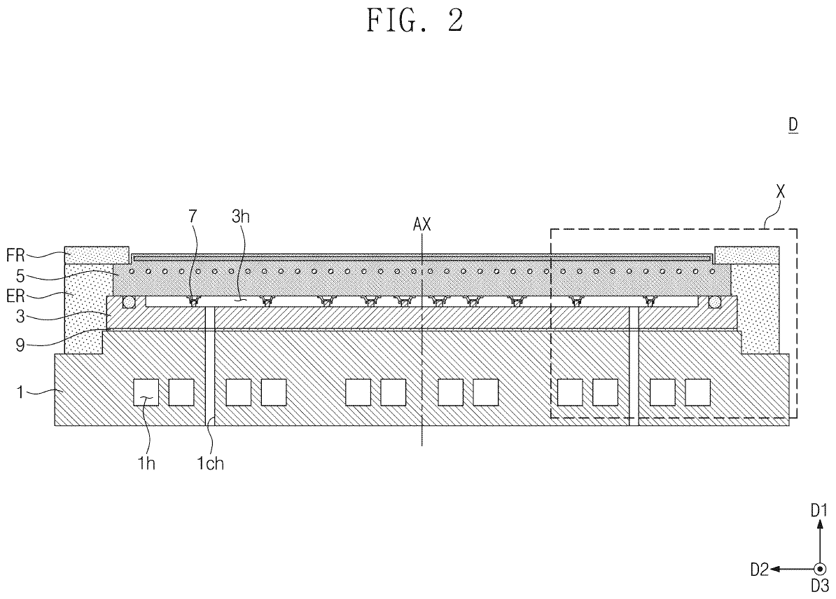

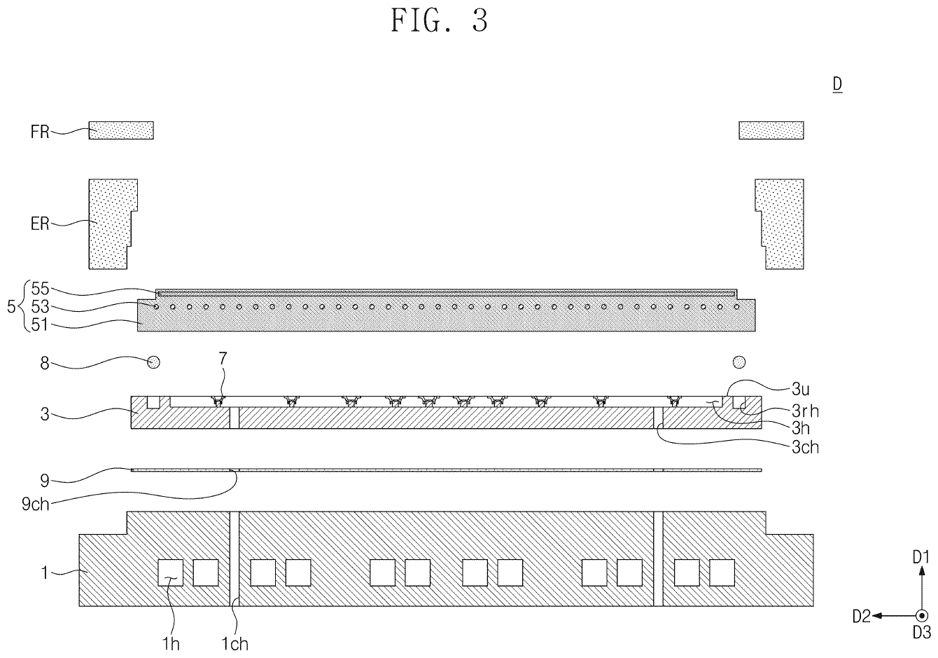

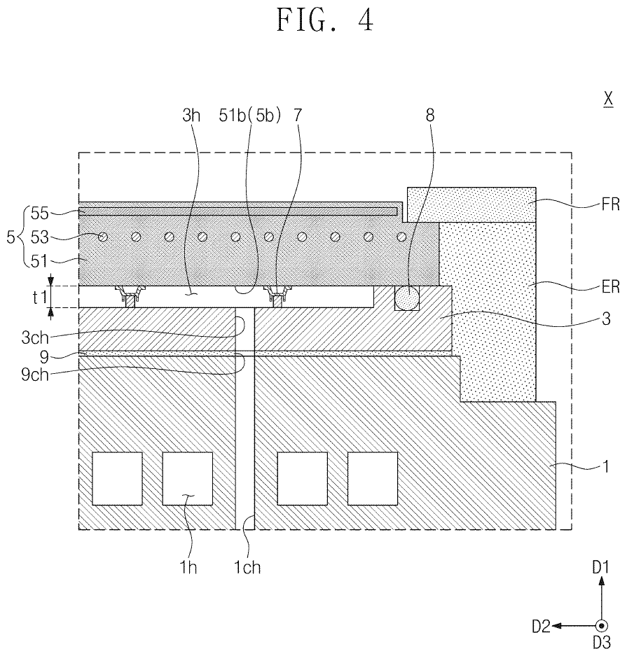

FIG. 2 is a sectional view illustrating a substrate supporting device according to an example embodiment of the inventive concepts, FIG. 3 is an exploded sectional view illustrating a substrate supporting device according to an example embodiment of the inventive concepts, and FIG. 4 is an enlarged sectional view illustrating a portion ‘X’ of FIG. 2.

Referring to FIGS. 2 to 4, the substrate supporting device D may include a cooling plate 1, a thermal-insulation plate 3, an adhesive layer 9, a chucking plate 5, a sealing member 8, a supporting structure 7, an edge ring ER, and a focus ring FR.

The cooling plate 1 may include a cooling hole 1h. The cooling hole 1h may be a part of a pathway, through which a coolant passes. The cooling hole 1h may be connected to a coolant supplying device (not shown). The coolant, which is supplied from the coolant supplying device, may absorb a heat energy from the cooling plate 1, while passing through the cooling hole 1h. The cooling plate 1 may be configured to support the thermal-insulation plate 3 and/or the chucking plate 5. The cooling plate 1 may be an element, which is configured to have a rotation symmetry about an axis AX parallel to the first direction D1, but the inventive concepts are not limited to this example. The cooling plate 1 may be formed of or include a metallic material. For example, the cooling plate 1 may be formed of or include aluminum (Al) or the like. However, the inventive concepts are not limited to this example. The cooling plate 1 may further include a connection hole 1ch. The connection hole 1ch may extend vertically. For example, the connection hole 1ch may penetrate the cooling plate 1 in the first direction D1. The connection hole 1ch may be connected to an adiabatic space 3h and the heat-transfer fluid control device HC (e.g., see FIG. 1). The heat-transfer fluid, which is supplied from the heat-transfer fluid control device HC, may be supplied into the adiabatic space 3h through the connection hole 1ch. Further, a fluidic material in the adiabatic space 3h may be exhausted to the outside through the connection hole 1ch. This will be described in more detail below.

The thermal-insulation plate 3 may be disposed on the cooling plate 1. The thermal-insulation plate 3 may be disposed below the chucking plate 5. A heat-transfer coefficient (HTC) of the thermal-insulation plate 3 may be smaller than a heat-transfer coefficient of the chucking plate 5. For example, the thermal-insulation plate 3 may be formed of or include a ceramic material. For example, the thermal-insulation plate 3 may be formed of or include Cordierite. A thickness of the thermal-insulation plate 3 may range from about 5 mm to about 6 mm.

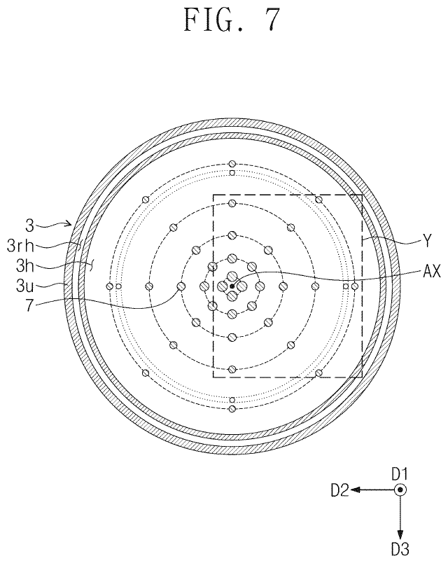

The thermal-insulation plate 3 may be configured to provide the adiabatic space 3h. The adiabatic space 3h may be a space, which is formed by recessing a top surface 3u of the thermal-insulation plate 3 by a specific depth in a downward direction. As shown in FIG. 7, the adiabatic space 3h may be circular, when viewed in a plan view, but the inventive concepts are not limited to this example. A thickness t1 of the adiabatic space 3h may be smaller than a thickness of the thermal-insulation plate 3. For example, the thickness t1 of the adiabatic space 3h may range from about 0.02 mm to about 2.00 mm. The adiabatic space 3h may be connected to the heat-transfer fluid control device HC (e.g., see FIG. 1). For example, the adiabatic space 3h may be connected to the heat-transfer fluid control device HC through the connection hole 1ch. A width of the adiabatic space 3h in a horizontal direction may be smaller than a width of the thermal-insulation plate 3 in the horizontal direction.

So far, the adiabatic space 3h has been illustrated and described as being defined by the thermal-insulation plate 3, but the inventive concepts are not limited to this example. In some example embodiments, the adiabatic space 3h may be provided between the cooling plate 1 and the chucking plate 5, without an additional thermal-insulation plate 3. In other words, the chucking plate 5 is vertically separated from the cooling plate 1 by an adiabatic space 3h, which is sealed and under the chucking plate 5 to expose the bottom surface of the chucking plate 5. For example, the adiabatic space 3h may be defined by an O-ring or the like, which may be placed between the cooling plate 1 and the chucking plate 5.

The thermal-insulation plate 3 may further include an upper connection hole 3ch. The upper connection hole 3ch may be extended from the adiabatic space 3h in a downward direction. The upper connection hole 3ch may be connected to a bottom surface of the thermal-insulation plate 3. The upper connection hole 3ch may be connected to the connection hole 1ch. In other words, the connection hole 1ch and the adiabatic space 3h may be connected to each other through the upper connection hole 3ch.

The thermal-insulation plate 3 may further include a sealing hole 3rh. The sealing hole 3rh may be a space, which is recessed from the top surface 3u of the thermal-insulation plate 3 in a downward direction. The sealing hole 3rh may be placed outside the adiabatic space 3h, when viewed in a plan view. The sealing hole 3rh may have a ring shape, as shown in FIG. 7, but the inventive concepts are not limited to this example. The sealing member 8 may be placed in the sealing hole 3rh.

The adhesive layer 9 may be placed between the cooling plate 1 and the thermal-insulation plate 3. The adhesive layer 9 may be used to fasten the thermal-insulation plate 3 to the cooling plate 1. The adhesive layer 9 may be formed of or include a silicone-based adhesive material. The adhesive layer 9 may include an intermediate connection hole 9ch. The intermediate connection hole 9ch may penetrate the adhesive layer 9 in a vertical direction. The intermediate connection hole 9ch may connect the connection hole 1ch to the upper connection hole 3ch.

The chucking plate 5 may be disposed on the thermal-insulation plate 3. A bottom surface 5b of the chucking plate 5 may be exposed to the adiabatic space 3h. The chucking plate 5 may include a plate body 51, a heater 53, and an electrode 55.

The plate body 51 may have the axis AX extending in the first direction D1. A bottom surface 51b of the plate body 51 may be exposed to the adiabatic space 3h. The plate body 51 may be formed of or include a ceramic material. A heat-transfer coefficient of the plate body 51 may be higher than a heat-transfer coefficient of the thermal-insulation plate 3. For example, the plate body 51 may be formed of or include aluminum nitride (AlN) or the like. A substrate may be disposed on a top surface of the plate body 51.

So far, the bottom surface 51b of the plate body 51 has been illustrated and described as being exposed to the adiabatic space 3h, but the inventive concepts are not limited to this example. In some example embodiments, another element may be disposed between the adiabatic space 3h and the bottom surface 51b of the plate body 51.

The heater 53 may be disposed in the plate body 51. If a heating power is applied to the heater 53, the heater 53 may emit heat, which is generate by the Joule heating process. Thus, a temperature of the plate body 51 may be increased. If the temperature of the plate body 51 is increased, the substrate on the plate body 51 may be heated. The heater 53 may be formed of or include a metallic material, but the inventive concepts are not limited to this example.

The electrode 55 may be disposed in the plate body 51. In an example embodiment, the electrode 55 may be placed at a level higher than the heater 53. If a power is applied to the electrode 55, plasma may be moved in the process space 2h (e.g., see FIG. 1). In some example embodiments, if the power is applied to the electrode 55, the substrate on the plate body 51 may be fastened to a specific position. For this, the electrode 55 may include aluminum (Al) or the like, but the inventive concepts are not limited to this example.

The sealing member 8 may be inserted in the sealing hole 3rh. The sealing member 8 may be in contact with a bottom surface of the plate body 51. The sealing member 8 may be formed of or include an elastic material. The sealing member 8 may have a ring shape. For example, the sealing member 8 may be an O-ring.

The supporting structure 7 may support the chucking plate 5. For example, the supporting structure 7 may be in contact with the bottom surface 51b of the plate body 51 and thus may be used to support the chucking plate 5. The supporting structure 7 will be described in more detail below.

The edge ring ER may be provided to enclose the cooling plate 1, the thermal-insulation plate 3, and/or the chucking plate 5. The focus ring FR may be placed on the edge ring ER. The focus ring FR may be formed of or include silicon (Si) and/or silicon carbide (SiC), but the inventive concepts are not limited to this example.

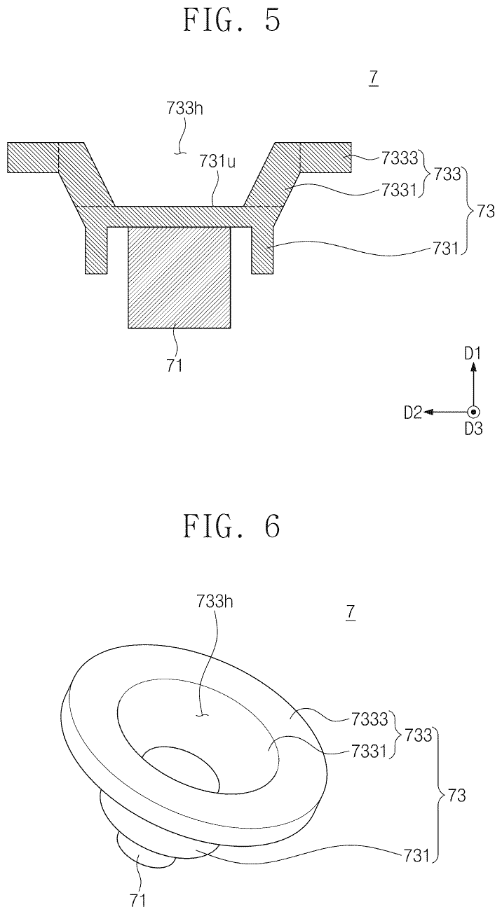

FIG. 5 is a sectional view illustrating a supporting structure of a substrate supporting device according to an example embodiment of the inventive concepts, and FIG. 6 is a perspective view illustrating a supporting structure of a substrate supporting device according to an example embodiment of the inventive concepts.

Referring to FIGS. 5 and 6, the supporting structure 7 may include a supporting block 71 and a cap 73.

The supporting block 71 may be disposed on a top surface of the thermal-insulation plate 3 (e.g., see FIG. 4). The supporting block 71 may be formed of or include a ceramic material. For example, the supporting block 71 may be formed of or include Cordierite. A thickness of the supporting block 71 may be smaller than a thickness of the adiabatic space 3h (e.g., see FIG. 4). The supporting block 71 and the thermal-insulation plate 3 may be provided to form a single object. However, the inventive concepts are not limited to this example, and in an example embodiment, the supporting block 71 may be separately formed regardless of the thermal-insulation plate 3, and then, may be combined or coupled to the top surface of the thermal-insulation plate 3.

The cap 73 may be disposed on the supporting block 71. The cap 73 may be in contact with the bottom surface 5b of the chucking plate 5 (e.g., see FIG. 4). A thermal expansion coefficient of the cap 73 may be higher than a thermal expansion coefficient of the chucking plate 5. For example, the thermal expansion coefficient of the cap 73 may range from about 23 to about 25. For this, the cap 73 may be formed of or include a metallic material. For example, the cap 73 may be formed of or include aluminum. In some example embodiment, the cap 73 may be formed of or include aluminum 6061 (Al6061).

The cap 73 may include a support member 731 and a cap body 733. The support member 731 may enclose an upper portion of the supporting block 71. The cap body 733 may be placed on the support member 731. The cap body 733 may have a cap inner hole 733h. The cap inner hole 733h may penetrate the cap body 733 in a vertical direction. A top surface 731u of the support member 731 may be exposed to the cap inner hole 733h. The cap body 733 may include a connection member 7331 and a contact member 7333. The connection member 7331 may be extended from the top surface 731u of the support member 731 in an upward direction. A diameter of the connection member 7331 may increase as a height in the upward direction increases. The contact member 7333 may extend from a side surface of an upper portion of the connection member 7331 in an outward direction. The contact member 7333 may have a ring shape, as shown in FIG. 6. A top surface of the contact member 7333 may be in contact with the bottom surface 5b of the chucking plate 5 (e.g., see FIG. 4). If a temperature of the supporting structure 7 increases, the supporting block 71 may vertically expand. In this case, the cap 73, which is in contact with the bottom surface 5b of the chucking plate 5 (e.g., see FIG. 4), may horizontally expand. Thus, even when the temperatures of the thermal-insulation plate 3 (e.g., see FIG. 4), the supporting structure 7, and the chucking plate 5 increase, the supporting structure 7 may be maintained to be in contact with the bottom surface 5b of the chucking plate 5.

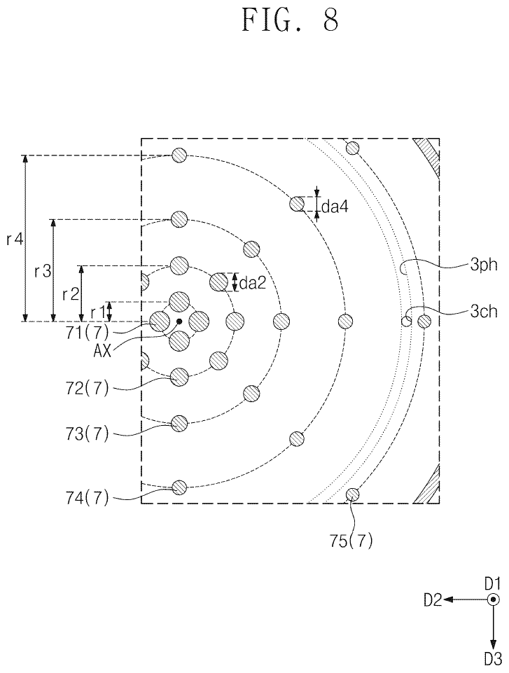

FIG. 7 is a plan view illustrating a thermal-insulation plate including a plurality of substrate supporting devices according to an example embodiment of the inventive concepts, and FIG. 8 is an enlarged plan view illustrating a portion ‘Y’ of FIG. 7.

Referring to FIGS. 7 and 8, the supporting structure 7 may be provided in plural.

The supporting structures 7 may include a first supporting structure 71, which is spaced apart from the axis AX by a first distance r1. In an example embodiment, the supporting structures 7 may include a plurality of first supporting structures 71. The first supporting structures 71 may be arranged in a circumference direction. However, in order to reduce complexity in the description, one of the first supporting structures 71 will be described as an example, unless the context clearly indicates otherwise.

The supporting structures 7 may include a second supporting structure 72, which is spaced apart from the axis AX by a second distance r2. In an example embodiment, the supporting structures 7 may include a plurality of second supporting structures 72. The second supporting structures 72 may be arranged in a circumference direction. However, in order to reduce complexity in the description, one of the second supporting structures 72 will be described as an example, unless the context clearly indicates otherwise.

The supporting structures 7 may include a third supporting structure 73, which is spaced apart from the axis AX by a third distance r3. In an example embodiment, the supporting structures 7 may include a plurality of third supporting structures 73. The third supporting structures 73 may be arranged in a circumference direction. However, in order to reduce complexity in the description, one of the third supporting structures 73 will be described as an example, unless the context clearly indicates otherwise.

The supporting structures 7 may include a fourth supporting structure 74, which is spaced apart from the axis AX by a fourth distance r4. In an example embodiment, the supporting structures 7 may include a plurality of fourth supporting structures 74. The fourth supporting structures 74 may be arranged in a circumference direction. However, in order to reduce complexity in the description, one of the fourth supporting structures 74 will be described as an example, unless the context clearly indicates otherwise.

As a distance from the axis AX increases, a size of the supporting structure 7 may decrease. For example, the second supporting structure 72 may be smaller than the first supporting structure 71. The third supporting structure 73 may be smaller than the second supporting structure 72. The fourth supporting structure 74 may be smaller than the third supporting structure 73. Here, the fourth distance r4 may be larger than the third distance r3. The third distance r3 may be larger than the second distance r2. The second distance r2 may be larger than the first distance r1.

The size of the supporting structure 7 may mean a size of the supporting structure 7 in a plan view, as shown in FIGS. 7 and 8. In other words, the size of the supporting structure 7 may mean the largest diameter of the cap 73 (e.g., see FIG. 5). For example, a size of the fourth supporting structure 74 may mean a diameter da4 of the fourth supporting structure 74 in a plan view, as shown in FIG. 8. Likewise, a size of the second supporting structure 72 may mean a diameter da2 of the second supporting structure 72 in a plan view, as shown in FIG. 8. The diameter da2 of the second supporting structure 72 may be larger than the diameter da4 of the fourth supporting structure 74, as shown in FIG. 8.

In an example embodiment, a distance between the second supporting structures 72 may be larger than a distance between the first supporting structures 71. A distance between the third supporting structures 73 may be larger than the distance between the second supporting structures 72. A distance between the fourth supporting structures 74 may be larger than the distance between the third supporting structures 73.

In an example embodiment, a difference between the second distance r2 and the first distance r1 may be smaller than a difference between the third distance r3 and the second distance r2. Further, the difference between the third distance r3 and the second distance r2 may be smaller than a difference between the fourth distance r4 and the third distance r3.

Referring to FIGS. 7 and 8, the thermal-insulation plate 3 may further include a migration hole 3ph. The migration hole 3ph may be extended in a circumference direction. The migration hole 3ph may be placed at a level between top and bottom ends of the upper connection hole 3ch shown in FIG. 4. In an example embodiment, the thermal-insulation plate 3 may have a plurality of upper connection holes 3ch. The upper connection holes 3ch may be spaced apart from each other. The upper connection holes 3ch may be connected to each other by the migration hole 3ph. However, in the following description, one of the upper connection holes 3ch will be described exemplarily, for the sake of brevity.

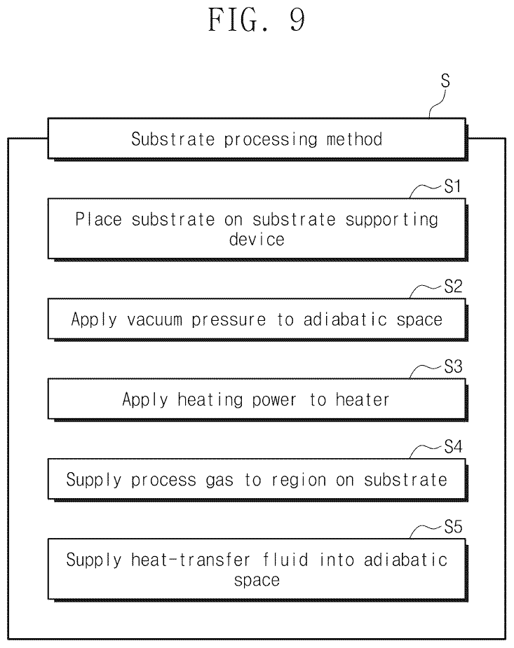

FIG. 9 is a flow chart illustrating a substrate processing method according to an example embodiment of the inventive concepts.

Referring to FIG. 9, a substrate processing method S may be provided. In the substrate processing method S, the substrate processing apparatus A described with reference to FIGS. 1 to 8 may be used to perform a process on a substrate. The substrate processing method S may include placing a substrate on a substrate supporting device (in S1), applying a vacuum pressure to an adiabatic space (in S2), applying a heating power to a heater (in S3), supplying a process gas to a region on the substrate (in S4), and supplying a heat-transfer fluid into the adiabatic space (in S5).

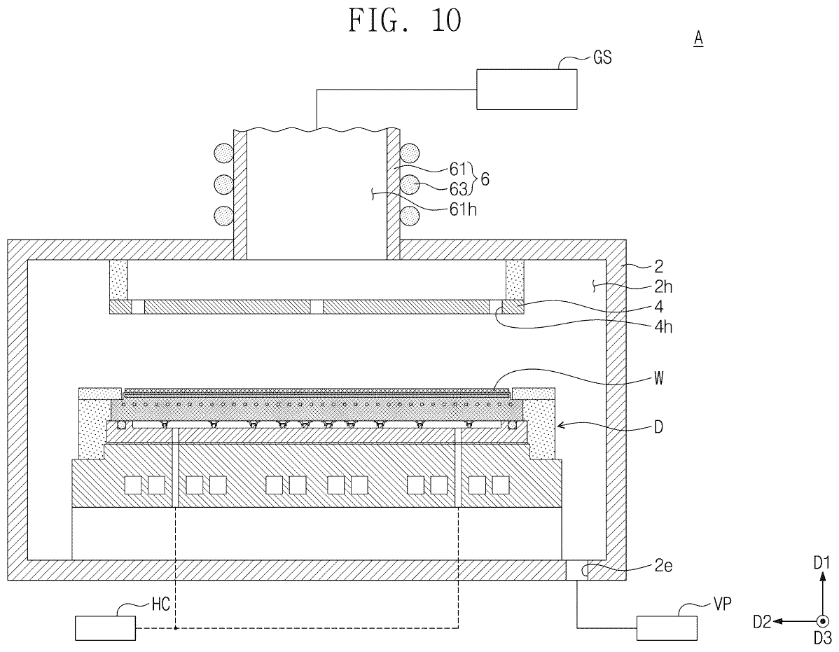

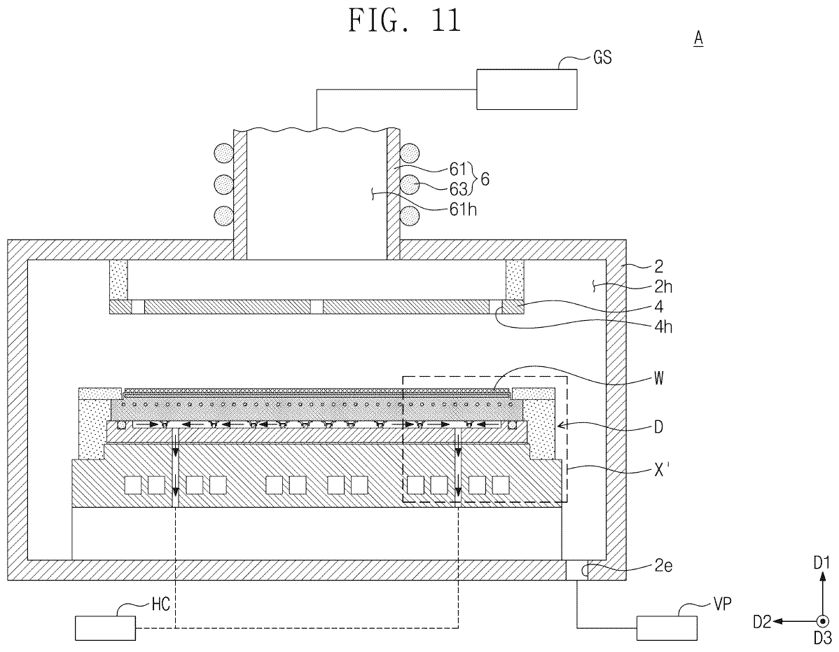

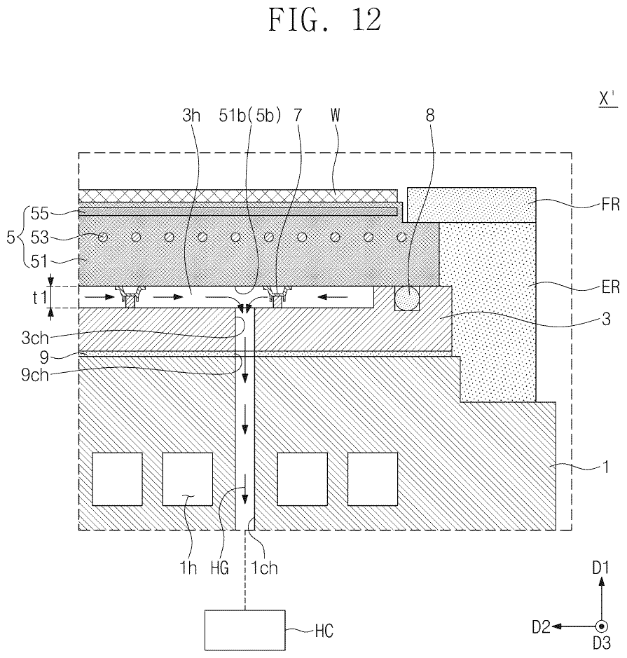

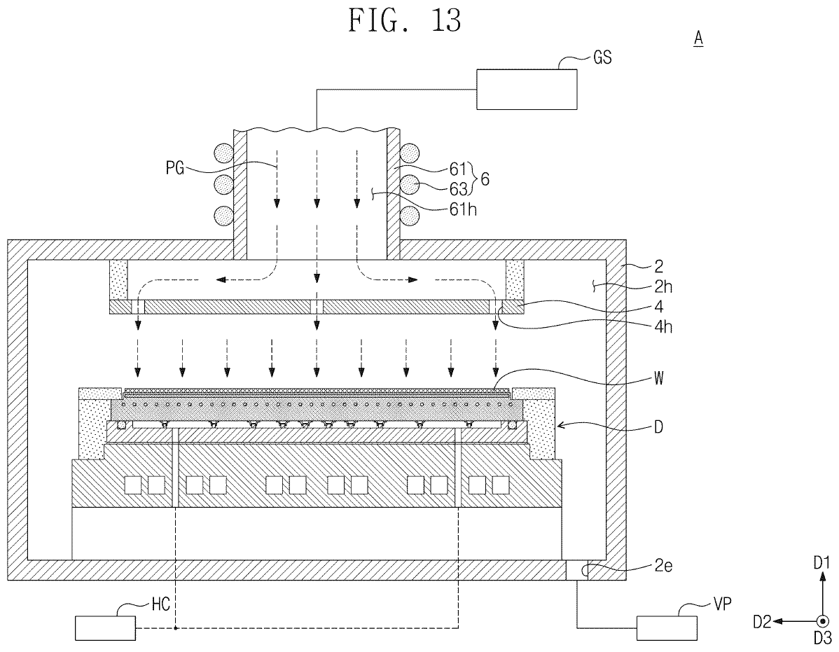

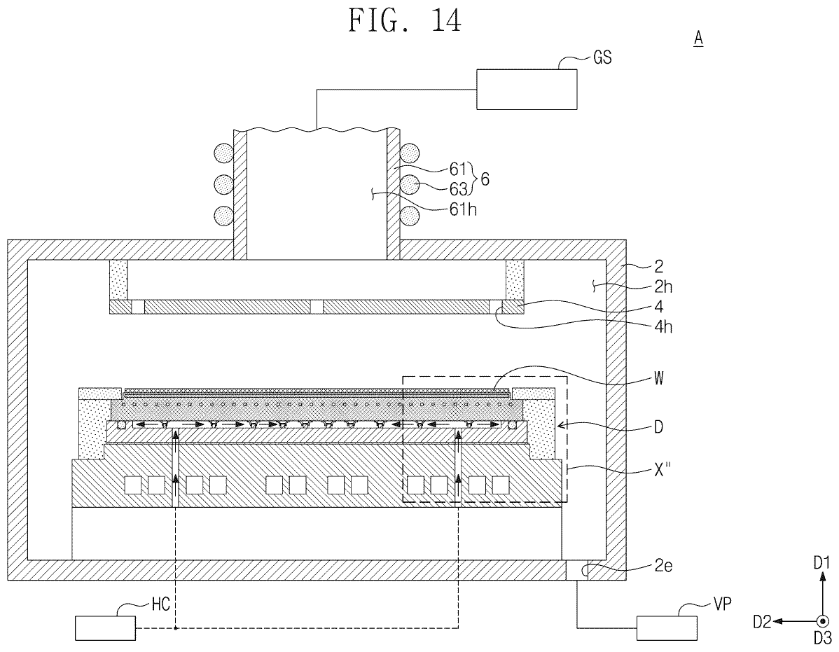

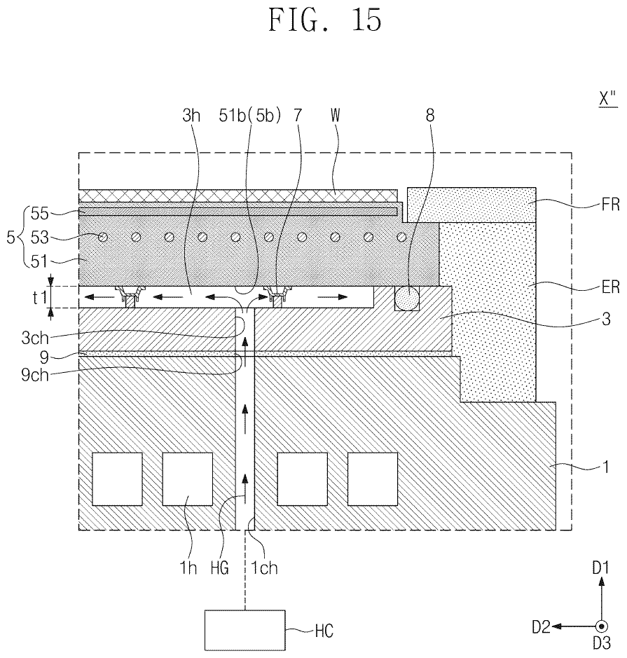

Hereinafter, the substrate processing method S of FIG. 9 will be described in more detail with reference to FIGS. 10 to 15.

FIGS. 10 to 15 are diagrams sequentially illustrating the substrate processing method according to the flow chart of FIG. 9.

Referring to FIGS. 10 and 9, the placing of the substrate on the substrate supporting device (in S1) may include fastening a substrate W to the substrate supporting device D. For example, the substrate W may be fastened to a top surface of the substrate supporting device D by an electrostatic force.

Referring to FIGS. 11, 12, and 9, the applying of the vacuum pressure to the adiabatic space (in S2) may include applying the vacuum pressure to the adiabatic space 3h when the substrate W is placed on the chucking plate 5. The heat-transfer fluid control device HC may be used to absorb a fluidic material in the adiabatic space 3h. For example, a heat-transfer fluid HG, which is present in the adiabatic space 3h, may sequentially pass through the upper connection hole 3ch, the intermediate connection hole 9ch, and the connection hole 1ch and may be exhausted to the outside. In this case, the adiabatic space 3h may be in a substantial vacuum state. A heat-transfer process between the chucking plate 5 and the cooling plate 1 may be suppressed.

The applying of the heating power to the heater (in S3) may include applying a heating power to the heater 53 while applying the vacuum pressure to the adiabatic space 3h. If the heating power is applied to the heater 53, the heater 53 may emit heat, which is generate by the Joule heating process. Thus, a temperature of the plate body 51 may increase.

In the case where the adiabatic space 3h is in the substantial vacuum state, the heat-transfer process from the chucking plate 5 to the cooling plate 1 may be reduced. Thus, even when the temperature of the plate body 51 is increased by the heater 53, an amount of heat, which is exhausted to the cooling plate 1, may be reduced. Thus, the heat of the plate body 51 may be transferred to the substrate W. Thus, the substrate W may be heated to a high temperature. For example, the substrate W may be heated to a temperature of about 300° C. or higher. In some example embodiments, the substrate W may be heated to a temperature of about 350° C. or higher.

Referring to FIGS. 13 and 9, the supplying of the process gas (in S4) may include supplying a process gas PG from the gas supplying device GS to the process space 2h. The process gas PG may be used in a process that is performed on the substrate W placed on the substrate supporting device D. For example, the process gas PG may be used to perform an etching process and/or a deposition process on the substrate W.

Referring to FIGS. 14, 15, and 9, the supplying of the heat-transfer fluid into the adiabatic space (in S5) may include supplying the heat-transfer fluid HG into the adiabatic space 3h using the heat-transfer fluid control device HC. If the adiabatic space 3h is filled with the heat-transfer fluid HG, the heat-transfer process from the plate body 51 to the cooling plate 1 may be effectively performed. Thus, the temperature of the plate body 51 may be lowered. If it is desired to lower the temperature of the substrate W, the heat-transfer fluid HG may be supplied into the adiabatic space 3h, as described above. In an example embodiment, the heat-transfer fluid HG may include helium (He), argon (Ar), and/or nitrogen (N2), but the inventive concepts are not limited to this example.

In a substrate supporting device according to an example embodiment of the inventive concepts, a substrate processing apparatus including the same, and/or a substrate processing method using the same, it may be possible to heat a substrate on a substrate supporting device to a high temperature. Thus, it may be possible to realize a high etch-ratio process on a substrate.

In a substrate supporting device according to an example embodiment of the inventive concepts, a substrate processing apparatus including the same, and/or a substrate processing method using the same, it may be possible to control a process of exhausting heat, which is generated by a heater, to a cooling plate. Thus, even when a chucking plate is heated to a high temperature, it may be possible to mitigate or prevent the cooling plate from being thermally damaged.

In a substrate supporting device according to an example embodiment of the inventive concepts, a substrate processing apparatus including the same, and/or a substrate processing method using the same, it may be possible to quickly control a temperature of a substrate, if desired. For example, the temperature of the substrate may be quickly increased by applying a vacuum pressure to an adiabatic space. Also, the temperature of the substrate may be quickly lowered by supplying a heat-transfer fluid into the adiabatic space.

In a substrate supporting device according to an example embodiment of the inventive concepts, a substrate processing apparatus including the same, and/or a substrate processing method using the same, even when a plate body is thermally deformed by a high temperature condition, a supporting structure may be elevated. Thus, even when the thermal deformation issue occurs, the supporting structure may be maintained to be in contact with a chucking plate. Thus, a heat-transfer process may be performed in a uniform manner.

In a substrate supporting device according to an example embodiment of the inventive concepts, a substrate processing apparatus including the same, and/or a substrate processing method using the same, a supporting structure near an edge region may be smaller than a supporting structure near a center region. Furthermore, a distance between the supporting structures near the edge region may be larger than a distance between the supporting structures near the center region. Thus, a heat-transfer process from a chucking plate to a cooling plate may be less activated near the edge region than near the center region. In this case, it may be possible to independently control the temperatures of the center and edge regions. For example, the edge region may be locally maintained to a high temperature. This may make it possible to reduce a variation in process characteristics between the edge region and the center region.

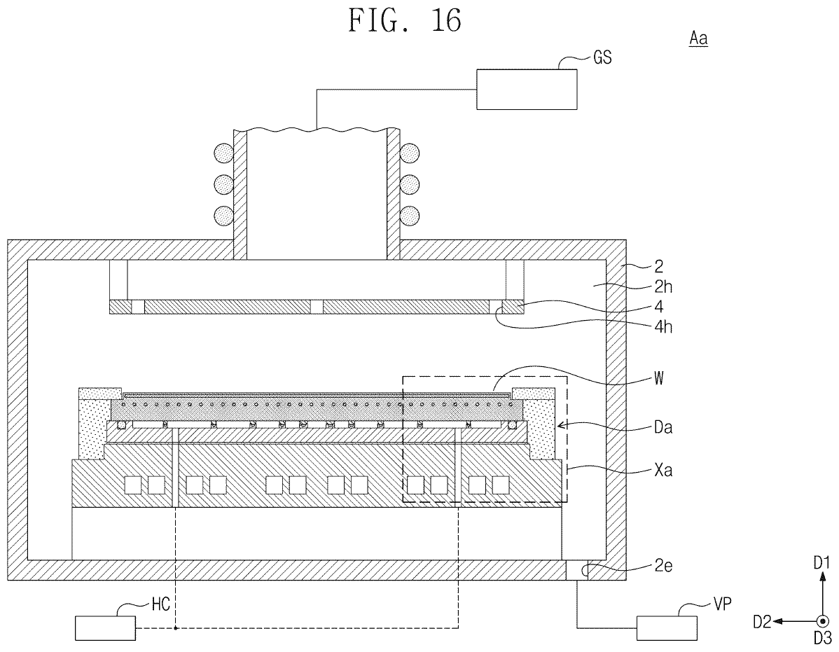

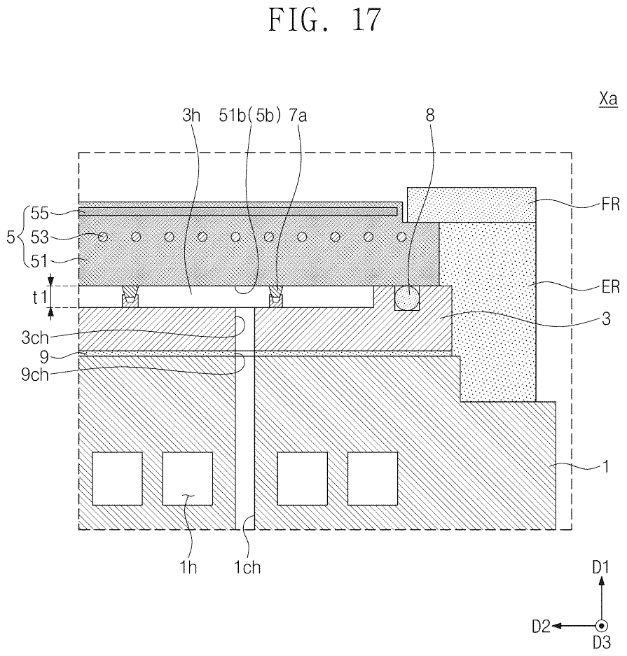

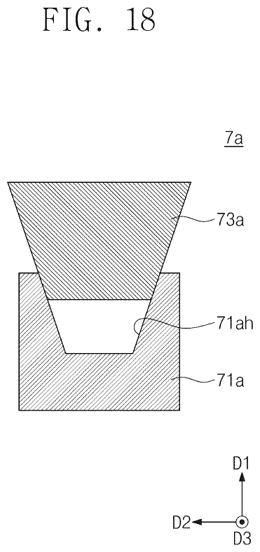

FIG. 16 is a sectional view illustrating a substrate processing apparatus according to an example embodiment of the inventive concepts, FIG. 17 is an enlarged sectional view illustrating a portion ‘Xa’ of FIG. 16, and FIG. 18 is a sectional view illustrating a supporting structure of a substrate supporting device according to an example embodiment of the inventive concepts.

In the following description, for concise description, an element previously described with reference to FIGS. 1 to 15 may be identified by the same reference number without repeating an overlapping description thereof.

Referring to FIGS. 16 to 18, a substrate processing apparatus Aa may be provided. The substrate processing apparatus Aa may include a substrate supporting device Da. The substrate supporting device Da may include a supporting structure 7a. The supporting structure 7a may include a supporting block 71a and a cap 73a. The supporting block 71a may have a support hole 71ah, which is recessed from a top surface of the supporting block 71a in a downward direction. A diameter of the support hole 71ah may decrease in a downward direction. The cap 73a may have a truncated-cone shape whose diameter increases in an upward direction. A portion of the cap 73a may be inserted in the support hole 71ah. If the supporting block 71a is heated, the cap 73a, which is inserted in the support hole 71ah, may be elevated. Thus, the chucking plate 5 may be maintained to be in contact with the supporting structure 7a.

In a substrate supporting device according to an example embodiment of the inventive concepts, a substrate processing apparatus including the same, and/or a substrate processing method using the same, it may be possible to heat a substrate to a high temperature.

In a substrate supporting device according to an example embodiment of the inventive concepts, a substrate processing apparatus including the same, and/or a substrate processing method using the same, it may be possible to mitigate or prevent components in the substrate supporting device from being thermally damaged.

In a substrate supporting device according to an example embodiment of the inventive concepts, a substrate processing apparatus including the same, and/or a substrate processing method using the same, it may be possible to quickly control a temperature of a substrate when desired.

In a substrate supporting device according to an example embodiment of the inventive concepts, a substrate processing apparatus including the same, and/or a substrate processing method using the same, it may be possible to suppress a deformation issue caused by thermal expansion.

In a substrate supporting device according to an example embodiment of the inventive concepts, a substrate processing apparatus including the same, and/or a substrate processing method using the same, it may be possible to independently control temperatures of edge and center regions of a substrate.

While some example embodiments of the inventive concepts have been particularly shown and described, it will be understood by one of ordinary skill in the art that variations in form and detail may be made therein without departing from the spirit and scope of the attached claims.

1. A substrate supporting device, comprising:
a cooling plate including a cooling hole;
a thermal-insulation plate on the cooling plate; and
a chucking plate placed on the thermal-insulation plate, the chucking plate comprising a heater,
wherein the thermal-insulation plate includes an adiabatic space, the adiabatic space recessed from a top surface of the thermal-insulation plate by a depth in a downward direction, and
the cooling plate includes a connection hole, the connection hole extending vertically and connected to the adiabatic space.

2. The device of claim 1, wherein a thickness of the adiabatic space ranges from 0.02 mm to 2.00 mm.

3. The device of claim 1, further comprising:
a supporting structure configured to support a bottom surface of the chucking plate,
wherein the supporting structure is within the adiabatic space.

4. The device of claim 3, wherein the supporting structure comprises:
a supporting block; and
a cap on the supporting block and configured to be in contact with the bottom surface of the chucking plate.

5. The device of claim 3, wherein
the supporting structure comprises a plurality of supporting structures,
the plurality of supporting structures comprise first supporting structures, which are spaced apart from an axis of the chucking plate by a first distance, and second supporting structures, which are spaced apart from the axis by a second distance,
a distance between the first supporting structures is smaller than a distance between the second supporting structures, and
the second distance is larger than the first distance.

6. The device of claim 1, wherein a heat-transfer coefficient of the thermal-insulation plate is smaller than a heat-transfer coefficient of the chucking plate.

7. The device of claim 1, wherein the thermal-insulation plate comprises a ceramic material.

8. A substrate supporting device, comprising:
a cooling plate with a cooling hole;
a chucking plate on the cooling plate; and
a supporting structure configured to support a bottom surface of the chucking plate,
wherein the chucking plate is vertically separated from the cooling plate by an adiabatic space, which is sealed and under the chucking plate to expose the bottom surface of the chucking plate,
the supporting structure is in the adiabatic space,
the cooling plate includes a connection hole connected to the adiabatic space, and
the supporting structure comprises,
a supporting block, and
a cap coupled to the supporting block and configured to be in contact with the bottom surface of the chucking plate.

9. The device of claim 8, wherein the cap comprises:
a support member enclosing an upper portion of the supporting block; and
a cap body on the support member,
wherein the cap body includes a cap inner hole vertically penetrating the cap body, and
a top surface of the support member is exposed to the cap inner hole.

10. The device of claim 9, wherein the cap body comprises:
a connection member extended from the top surface of the support member in an upward direction; and
a contact member extended from a side surface of an upper portion of the connection member in an outward direction, the contact member having a ring shape,
wherein a top surface of the contact member is in contact with the bottom surface of the chucking plate.

11. The device of claim 10, wherein a diameter of the connection member increases in an upward direction.

12. The device of claim 8, wherein the cap has a truncated-cone shape whose diameter increases in an upward direction.

13. The device of claim 12, wherein
the supporting block includes a support hole, which is recessed from a top surface of the supporting block in a downward direction,
a diameter of the support hole decreases in the downward direction, and
a portion of the cap is inserted in the support hole.

14. The device of claim 8, wherein
the supporting structure comprises a plurality of supporting structures,
the plurality of supporting structures comprise a first supporting structure and a second supporting structure, the first supporting structure spaced apart from an axis of the chucking plate by a first distance, the second supporting structure spaced apart from the axis by a second distance,
a size of the first supporting structure is larger than a size of the second supporting structure, and
the second distance is larger than the first distance.

15. The device of claim 8, wherein
the supporting structure comprises a plurality of supporting structures,
the plurality of supporting structures comprise first supporting structures and second supporting structures, the first supporting structures spaced apart from an axis of the chucking plate by a first distance, the second supporting structures spaced apart from the axis by a second distance,
a distance between the first supporting structures is smaller than a distance between the second supporting structures, and
the second distance is larger than the first distance.

16. The device of claim 8, further comprising:
a thermal-insulation plate between the cooling plate and the chucking plate,
wherein the supporting block is on a top surface of the thermal-insulation plate.

17. The device of claim 8, wherein a thermal expansion coefficient of the cap is higher than a thermal expansion coefficient of the chucking plate.

18. A substrate processing apparatus, comprising:
a process chamber including a process space; and
a substrate supporting device in the process chamber,
wherein the substrate supporting device comprises,
a cooling plate with a cooling hole;
a chucking plate on the cooling plate, the chucking plate including a heater; and
a plurality of supporting structures configured to support a bottom surface of the chucking plate,
wherein the chucking plate is vertically separated from the cooling plate by an adiabatic space, which is sealed and under the chucking plate to expose the bottom surface of the chucking plate,
the plurality of supporting structures comprise a first supporting structure and a second supporting structure, the first supporting structure is spaced apart from an axis of the chucking plate by a first distance, the second supporting structure is spaced apart from the axis by a second distance, and
a size of the first supporting structure is larger than a size of the second supporting structure.

19. The apparatus of claim 18, wherein the second distance is larger than the first distance.

20. The apparatus of claim 18, wherein each of the plurality of supporting structures comprises:
a supporting block; and
a cap coupled to the supporting block and configured to be in contact with the bottom surface of the chucking plate.

21.-25. (canceled)
